(19) United States
(12) Patent Application Publication
(10) Pub. No.: US 2021/0069761 A1
(43) Pub. Date: Mar. 11, 2021

(54) SUPPORT BRACKET AND CLEANING DEVICE HAVING THE SAME

(71) Applicant: TRIPLE WIN TECHNOLOGY(SHENZHEN) CO.LTD., Shenzhen (CN)

(72) Inventor: SHENG LIU, Shenzhen (CN)

(21) Appl. No.: 16/677,807

(22) Filed: Nov. 8, 2019

(30) Foreign Application Priority Data
Sep. 10, 2019 (CN) 201921530533.5

(51) Int. Cl. B08B 11/02; H05K 3/26

(52) U.S. Cl. CPC B08B 11/02; H05K 2203/0165; H05K 3/26

(57) ABSTRACT

A support bracket for a manufacturer which prevents trays of cleanable devices supported thereon from being stacked together includes a front outer strip, a left outer strip, a rear outer strip, and a right outer strip connected in that order. The front outer strip faces the rear outer strip, the left outer strip faces the right outer strip. The bracket body further comprises at least one horizontal inner strip and at least one vertical inner strip. Each horizontal inner strip is connected between the front outer strip and the rear outer strip. Each vertical inner strip is connected between the left outer strip and the right outer strip and intersects with the horizontal inner strip. The bracket body is divided by the horizontal inner strip and the vertical inner strip into a plurality of sub bracket bodies. A cleaning device having the support bracket is also provided.

### FIELD

The subject matter relates to industrial handling and processes.

### BACKGROUND

Camera modules may have flexible circuit boards. The flexible circuit board needs to be cleaned before the flexible circuit board is mounted into the camera module.

In order to improve cleaning efficiency, a number of flexible circuit boards are placed in a tray before cleaning. A number of trays having the flexible circuit boards are placed on a bracket. Then, the bracket having the trays is loaded into a plasma cleaning device to clean the flexible circuit boards. However, the trays may be stacked together because the trays cannot be fixed on top of the brackets. Such a tray configuration is not efficient in cleaning the flexible circuit boards.

Therefore, there is room for improvement in the art.

### BRIEF DESCRIPTION OF THE DRAWINGS

Implementations of the present technology will now be described, by way of embodiment, with reference to the attached figures.

FIG. 1 is a diagrammatic view of an embodiment of a support bracket according to the present disclosure.

FIG. 2 is similar to FIG. 1, but showing the support bracket from another angle.

FIG. 3 is a diagrammatic view of an embodiment of a tray.

FIG. 4 is diagrammatic view of an embodiment of a cleaning device according to the present disclosure.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

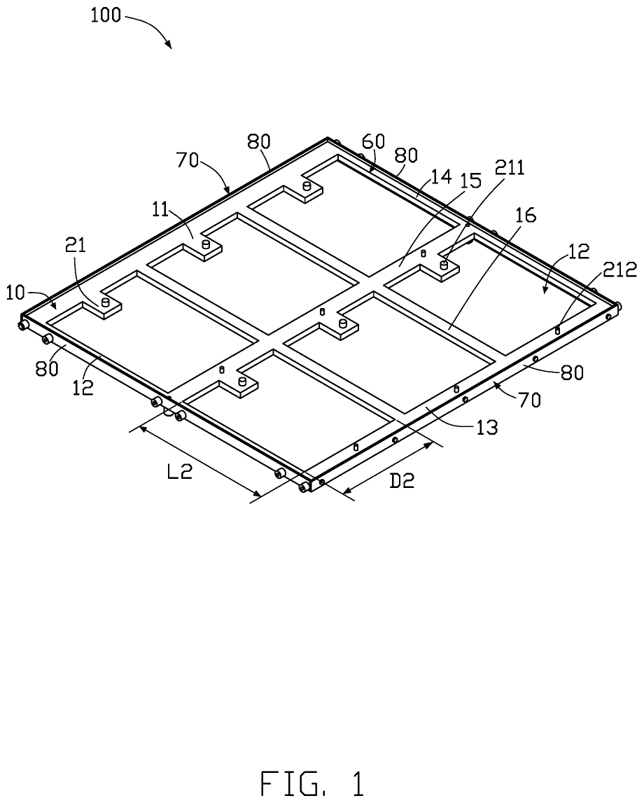

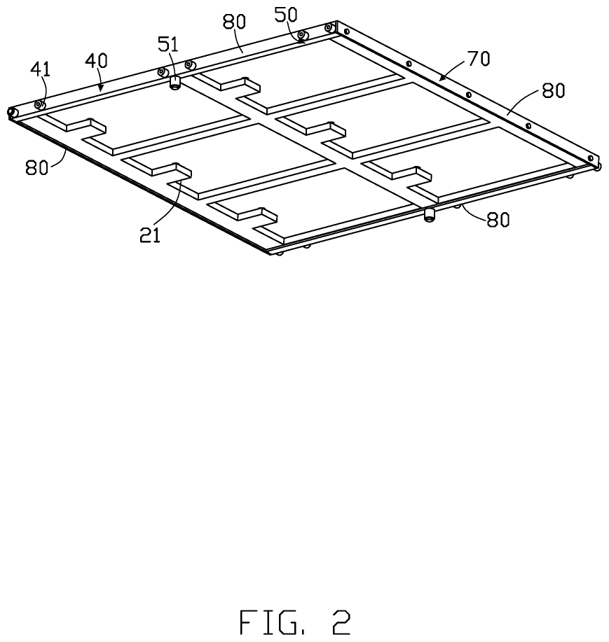

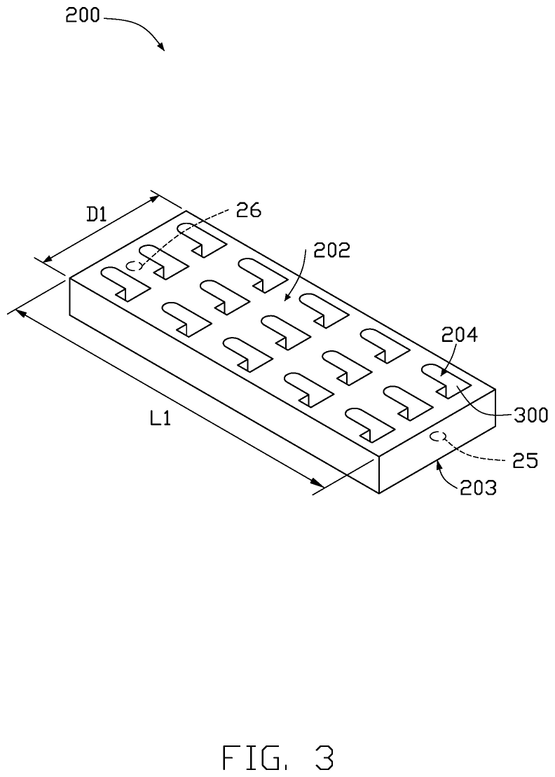

FIGS. 1 and 2 illustrate a support bracket 100 to carry a number of trays 200. The support bracket 100 comprises a hollow bracket body 10. The bracket body 10 comprises a front outer strip 11, a left outer strip 12, a rear outer strip 13, and a right outer strip 14 connected in that order. The front outer strip 11 faces and is parallel to the rear outer strip 13. The left outer strip 12 faces and is parallel to the right outer strip 14. The bracket body 10 further comprises at least one horizontal inner strip 15 and at least one vertical inner strip 16. Each horizontal inner strip 15 is connected between the front outer strip 11 and the rear outer strip 13. Each vertical inner strip 16 is connected between the left outer strip 12 and the right outer strip 14, and intersects with the horizontal inner strip 15. Thus, the bracket body 10 is divided by the horizontal inner strips 15 and the vertical inner strips 16 into a number of hollow sub bracket bodies 20. Each sub bracket body 20 carries one tray 200 (see FIG. 3), which prevents the trays from being stacked together. Furthermore, a total weight of the support bracket 100 is decreased. The bracket body 10 and the sub bracket body 20 can be rectangular. In other embodiments, the shapes of the bracket body 10 and the sub bracket body 20 can also be varied.

Referring to FIG. 3, the tray 200 comprises an upper surface 202 and a lower surface 203 opposite to the upper surface 202. The tray 200 defines a number of receiving grooves 204 on the upper surface 202. The receiving grooves 204 can receive a number of cleanable members 300. In at least one embodiment, the cleanable members 300 can be flexible circuit boards for camera modules. In at least one embodiment, the tray 200 further defines a first positioning hole 205 and a second positioning hole 206 on the lower surface 203. The first positioning hole 205 and the second positioning hole 206 can be adjacent to edges of the tray 200.

Referring to FIGS. 1 and 2, each sub bracket body 20 comprises a tab 21 protruding from an inner wall of the sub bracket body 20. The tab 21 comprises a first positioning post 211. The first positioning post 211 is inserted into the first positioning hole 205, thereby positioning the tray 200 on the sub bracket body 20. The tab 21 can be positioned at the front outer strip 11 or the horizontal inner strip 15.

Each sub bracket body 20 further comprises a second positioning post 212 protruding from a surface of the sub bracket body 20. The second positioning post 212 is inserted into the second positioning hole 206, thereby further positioning the tray 200 on the sub bracket body 20. The second positioning post 212 can be positioned on the rear outer strip 13 or the horizontal inner strip 15.

The height of the second positioning post 212 can be less than the height of the first positioning post 211. The tray 200 can be pre-positioned on the sub bracket body 20 through the height of the second positioning post 212, and then finally positioned on the height of the second positioning post 212 through the first positioning post 211.

In at least one embodiment, the length L1 of the tray 200 along the vertical inner strip 16 is less than the length L2 of the sub bracket body 20 along the vertical inner strip 16, to cause a portion of the sub bracket body 20 to be exposed from the tray 200. Thus, the exposed portion of the sub bracket body 20 facilitates the operation of the tray 200, for example, to separate the tray 200 from the sub bracket body 20. The tab 21 can be positioned at the exposed portion of the sub bracket body 20. Furthermore, the width D1 of the tray 200 along the horizontal inner strip 15 is greater than the width L2 of the sub bracket body 20 along the horizontal inner strip 15, to allow the sub bracket body 20 to carry and support the tray 200.

In at least one embodiment, the bracket body 10 comprises a first outer sidewall 40 at each of the left outer strip 12 and the right outer strip 14. The support bracket 100 further comprises a number of first wheels 41 mounted on the first outer sidewall 40. The first wheels 41 facilitates pushing the support bracket 100 along the extending direction of the first outer sidewall 40.

The bracket body 10 further comprises a lower surface 50 facing away from the lower surface 203 of the tray 200. The support bracket 100 further comprises a number of second wheels 51 mounted on the lower surface 50.

In at least one embodiment, the bracket body 10 further comprises an upper surface 60 opposite to the lower surface 50. The bracket body 10 further comprises a second outer sidewall 70 at each of the front outer strip 11 and the rear outer strip 13. A stopping plate 80 is fixed on each of the first outer sidewall 40 and the second outer sidewall 70. The stopping plate 80 protrudes from the upper surface 60 to prevent the tray 200 from being separated from the support bracket 100.

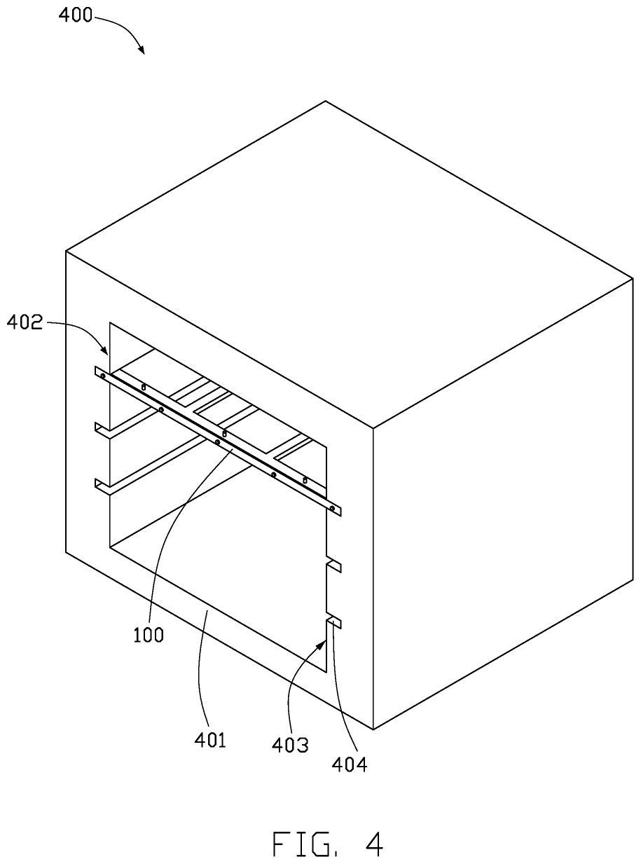

FIG. 4 illustrates an embodiment of a cleaning device 400. The cleaning device 400 can be a plasma cleaning device.

The cleaning device 400 comprises a casing 401 for receiving the support bracket 100. The casing 401 comprises a first inner sidewall 402 and a second inner sidewall 403 opposite to the first inner sidewall 402. Each of the first inner sidewall 402 and the second inner sidewall 403 defines a number of sliding grooves 404. The sliding grooves 404 on the first inner sidewall 402 correspond to the sliding grooves 404 on the second inner sidewall 403. The left outer strip 12 and the right outer strip 14 of the support bracket 100 can be slidably received in one sliding groove 402 on the first inner sidewall 402 and one corresponding sliding groove 404 on the second inner sidewall 403, respectively.

More specifically, the first wheels 41 can slide in the sliding grooves 402. The second wheels 51 can slide on the first inner sidewall 402 and the second inner sidewall 403. Thus, the second wheels 51 and the first wheels 41 cooperatively define the moving direction of the support bracket 100.

With the above configuration, through the engagement between the first positioning post and the first positioning hole, the tray can be positioned on the support bracket, and stacking of trays on one support bracket is prevented.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present exemplary embodiments, to the full extent indicated by the plain meaning of the terms in which the appended claims are expressed.

What is claimed is:

1. A support bracket comprising:
a bracket body comprising a front outer strip, a left outer strip, a rear outer strip, and a right outer strip connected in that order;
wherein the front outer strip faces the rear outer strip, the left outer strip faces the right outer strip, the bracket body further comprises at least one horizontal inner strip and at least one vertical inner strip, each of the at least one horizontal inner strip is connected between the front outer strip and the rear outer strip, each of the at least one vertical inner strip is connected between the left outer strip and the right outer strip, each of the at least one vertical inner strip intersects with the at least one horizontal inner strip, the bracket body is divided by the at least one horizontal inner strip and the at least one vertical inner strip into a plurality of sub bracket bodies.

2. The support bracket of claim 1, wherein each of the plurality of sub bracket bodies comprises a tab protruding from an inner wall of the sub bracket body, and the tab comprises a first positioning post.

3. The support bracket of claim 2, wherein each of the plurality of sub bracket bodies further comprises a second positioning post protruding from a surface of the sub bracket body.

4. The support bracket of claim 3, wherein a height of the second positioning post is less than a height of the first positioning post.

5. The support bracket of claim 1, wherein the bracket body comprises a first outer sidewall at each of the left outer strip and the right outer strip, and the support bracket further comprises a plurality of first wheels mounted on the first outer sidewall.

6. The support bracket of claim 1, wherein the bracket body further comprises a lower surface, and the support bracket further comprises a plurality of second wheels mounted on the lower surface.

7. The support bracket of claim 6, wherein the bracket body further comprises an upper surface opposite to the lower surface, the bracket body further comprises a second outer sidewall at each of the front outer strip and the rear outer strip, a stopping plate is fixed on each of the first outer sidewall and the second outer sidewall, and the stopping plate protrudes from the upper surface.

8. A cleaning device comprising:
a support bracket received in the casing, the support bracket comprising a bracket body, the bracket body comprising a front outer strip, a left outer strip, a rear outer strip, and a right outer strip connected in that order; and
a plurality of trays;
wherein the front outer strip faces the rear outer strip, the left outer strip faces the right outer strip, the bracket body further comprises at least one horizontal inner strip and at least one vertical inner strip, each of the at least one horizontal inner strip is connected between the front outer strip and the rear outer strip, each of the at least one vertical inner strip is connected between the left outer strip and the right outer strip, each of the at least one vertical inner strip intersects with the at least one horizontal inner strip, the bracket body is divided by the at least one horizontal inner strip and the at least one vertical inner strip into a plurality of sub bracket bodies for carry the plurality of trays.

9. The cleaning device of claim 8, further comprising a casing, wherein the casing comprises a first inner sidewall and a second inner sidewall opposite to the first inner sidewall, each of the first inner sidewall and the second inner sidewall defines at least one sliding groove, the at least one sliding groove on the first inner sidewall corresponds to the at least one sliding groove on the second inner sidewall, the left outer strip and the right outer strip of the support bracket is slidably receive in one of the at least one sliding groove on the first inner sidewall and the corresponding one of the at least one sliding groove on the second inner sidewall, respectively.

10. The cleaning device of claim 9, wherein the bracket body comprises a first outer sidewall at each of the left outer strip and the right outer strip, and the support bracket further comprises a plurality of first wheels mounted on the first outer sidewall, and the plurality of first wheels slides in the sliding grooves.

11. The cleaning device of claim 10, wherein the bracket body further comprises a lower surface, the support bracket further comprises a plurality of second wheels mounted on the lower surface, and the plurality of second wheels slides on the first inner sidewall and the second inner sidewall.

12. The cleaning device of claim 8, wherein the each of the plurality of sub bracket bodies comprises a tab protruding from an inner wall of the sub bracket body, the tab comprises a first positioning post, each of the plurality of trays comprises a lower surface, a first positioning hole is defined on the lower surface, and the first positioning post is inserted into the first positioning hole.

13. The cleaning device of claim 12, wherein each of the plurality of sub bracket bodies further comprises a second positioning post protruding from a surface of the sub bracket body, a second positioning hole is defined on the lower surface, and the second positioning post is inserted into second first positioning hole.

14. The cleaning device of claim 13, wherein a height of the second positioning post is less than a height of the first positioning post.

15. The support bracket of claim 11, wherein the bracket body further comprises an upper surface opposite to the lower surface, the bracket body further comprises a second outer sidewall at each of the front outer strip and the rear outer strip, a stopping plate is fixed on each of the first outer sidewall and the second outer sidewall, and the stopping plate protrudes from the upper surface.

16. The support bracket of claim 8, wherein a length of each of the plurality of trays along the vertical inner strip is less than a length of each of the plurality of sub bracket bodies along the vertical inner strip, to cause a portion of the sub bracket body to be exposed from the tray.

17. The support bracket of claim 8, wherein a width of each of the plurality of trays along the horizontal inner strip is greater than a width of each of the plurality of sub bracket bodies along the horizontal inner strip.
